(19) United States
(12) Patent Application Publication
(10) Pub. No.: US 2009/0059525 A1
(43) Pub. Date: Mar. 5, 2009

(54) HEAT DISSIPATION DEVICE FOR COMPUTER ADD-ON CARDS

(75) Inventors: XUE-WEN PENG, Shenzhen (CN); JUN-HAI LI, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/850,621

(22) Filed: Sep. 5, 2007

(51) Int. Cl. H05K 7/20

(52) U.S. Cl. 361/697

(57) ABSTRACT

A heat dissipation device mounted on a heat-generating component of a graphics card, includes a base, a fin unit and a fan. The base is kept in intimate contact with the heat-generating component. The fin unit includes a plurality of fins arranged on the base and forming a plurality of air passages between each fin and its neighboring fins. The fan is mounted on the base, close to the fin unit and producing airflow in the air passages. The base comprises a spreader inlayed in the base. The spreader is a flattened heat pipe. A bottom surface of the spreader is in contact with the heat-generating component. The fin unit is thermally attached to a top surface of the spreader.

### BACKGROUND OF THE INVENTION

1. Field of the Invention

The present invention relates to heat dissipation devices and particularly a heat dissipation device for a computer add-on card to dissipate heat generated by the card.

2. Description of Related Art

In order to enable desktop and other computers to rapidly process graphics and game technology, add-on units, generally referred to as “graphics cards” are often installed in computer devices. Such cards comprise a separate processor, called a GPU (graphics processor unit). The GPU generates a large amount of heat during operation. When the temperature of the GPU exceeds a certain level, the GPU may malfunction, or in the worst case fail outright. For this reason, a heat dissipation unit such as a heat sink is commonly required to be installed onto the GPU to dissipate the heat generated by the GPU and other electronic components adjacent to it into ambient air.

Conventionally, the heat sink comprises a solid base and a plurality of fins arranged on the base. The base is attached to the GPU mounted on the graphics card so as to absorb the heat. However, only a part of the base, usually a middle part, contacts the GPU. The heat originating from the GPU is directly absorbed by the middle part of the base and cannot quickly spread to other parts of the base. This results in an overheating of the middle part of the base, while the temperature of the other parts of the base have low temperatures relative to the middle part. The fins on the other parts of the base away from the middle part are not efficiently used. The efficiency of the heat sink needs to be improved through sufficient use of all of the fins on the base.

Accordingly, what is needed is a heat dissipation device with an enhanced heat dissipation performance.

### SUMMARY OF THE INVENTION

A heat dissipation device mounted on a heat-generating component of a graphics card, includes a base, a fin unit and a fan. The base is kept in intimate contact with the heat-generating component. The fin unit includes a plurality of fins arranged on the base and forming a plurality of air passage between each fin and its neighboring fins. The fan is mounted on the base, close to the fin unit and producing airflow in the air passages. The base comprises a spreader inlayed in the base, the spreader is a flattened heat pipe, a bottom surface of the spreader is in contact with the heat-generating component, and the fin unit is thermally attached to a top surface of the spreader.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views. Other advantages and novel features will become more apparent from the following detailed description of preferred embodiment when taken in conjunction with the accompanying drawings, in which:

FIG. 1 is an assembled view of a heat dissipation device in accordance with a preferred embodiment of the present invention;

FIG. 2 is an exploded, isometric view of FIG. 1;

FIG. 3 is an assembled view of a base of the heat dissipation device of FIG. 2;

FIG. 4 is an inverted view of a spreader of the base of FIG. 3; and

FIG. 5 is an inverted view of the base of FIG. 3.

### DETAILED DESCRIPTION OF THE INVENTION

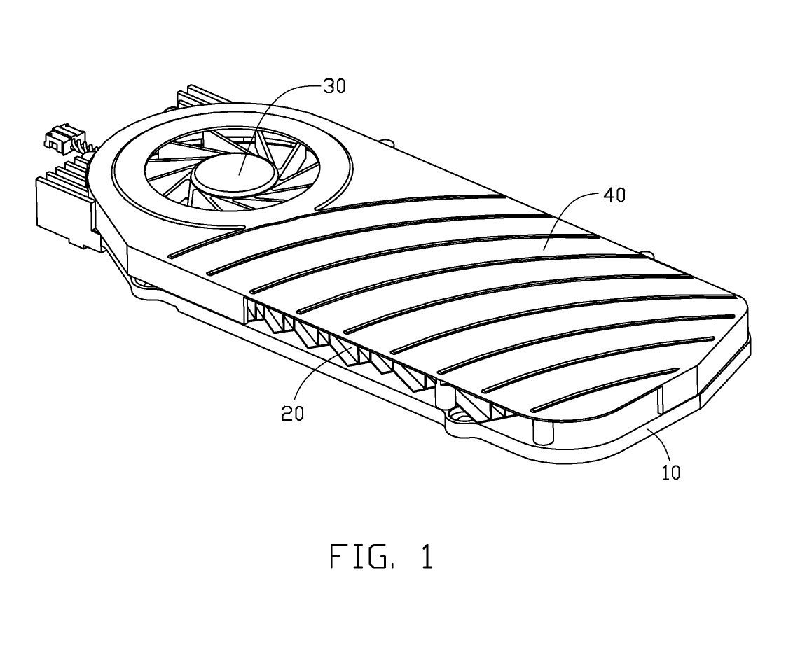

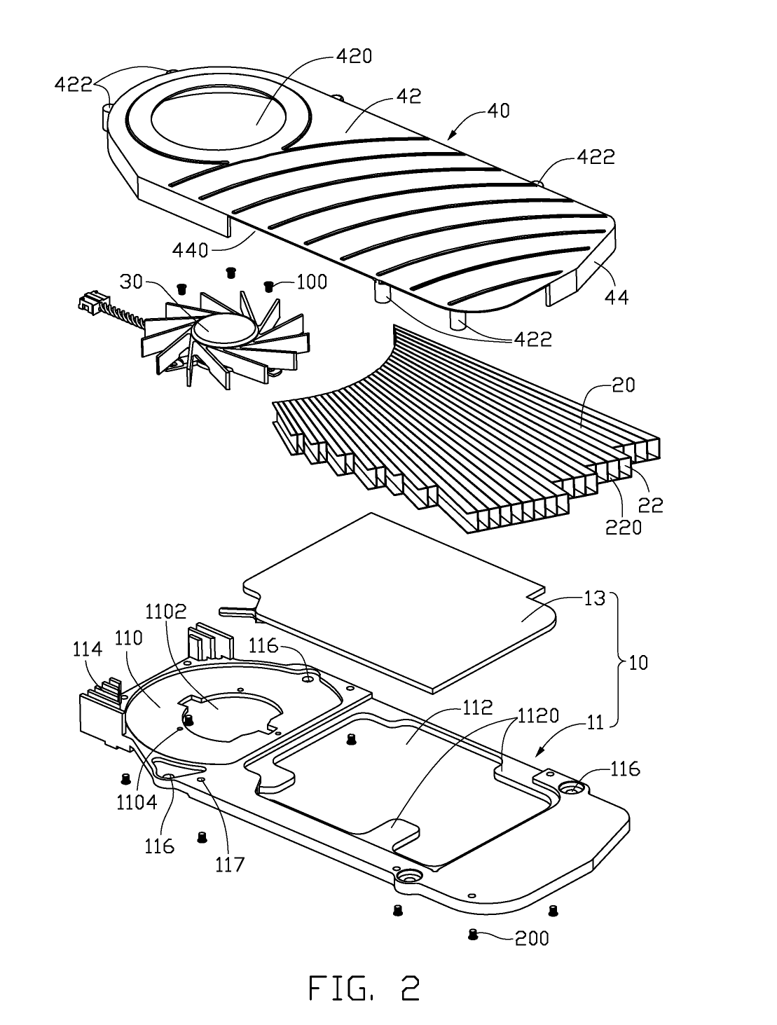

Referring to FIGS. 1-2, a heat dissipation device in accordance with a preferred embodiment of the present invention is adapted for removing heat from a heat-generating electronic component such as a GPU (graphics processor unit) mounted on a computer add-on card (not shown).

The heat dissipation device comprises a base 10 kept in contact with the GPU, a fin unit 20 arranged on one end of the base 10, a fan 30 mounted at another end of the base 10 for producing airflow to the fin unit 20, and a cover body 40 disposed on the base 10 and covering the fan 30 and the fin unit 20.

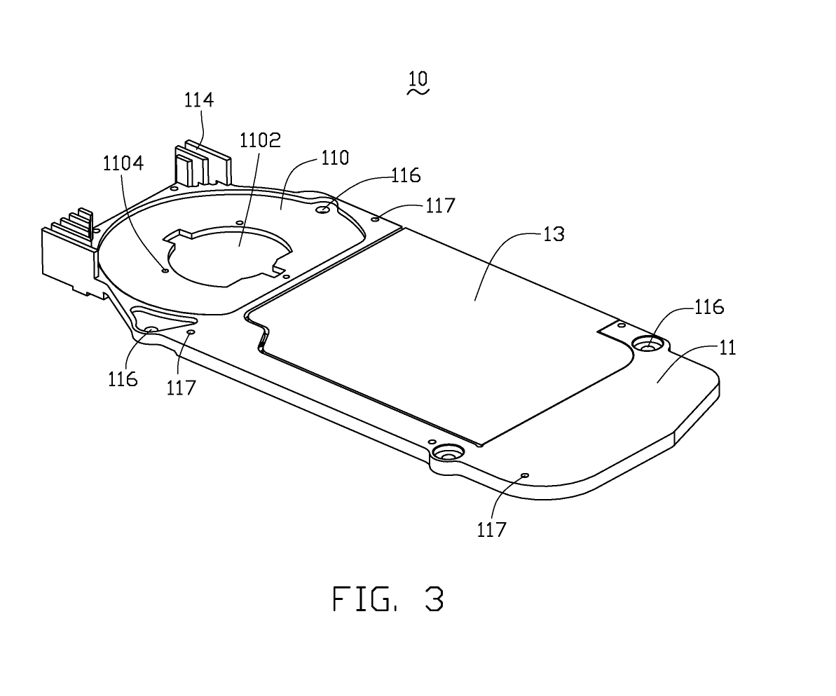

Referring also to FIGS. 3-5, the base 22 comprises a frame 11 and a spreader 13 inlayed in the frame 11.

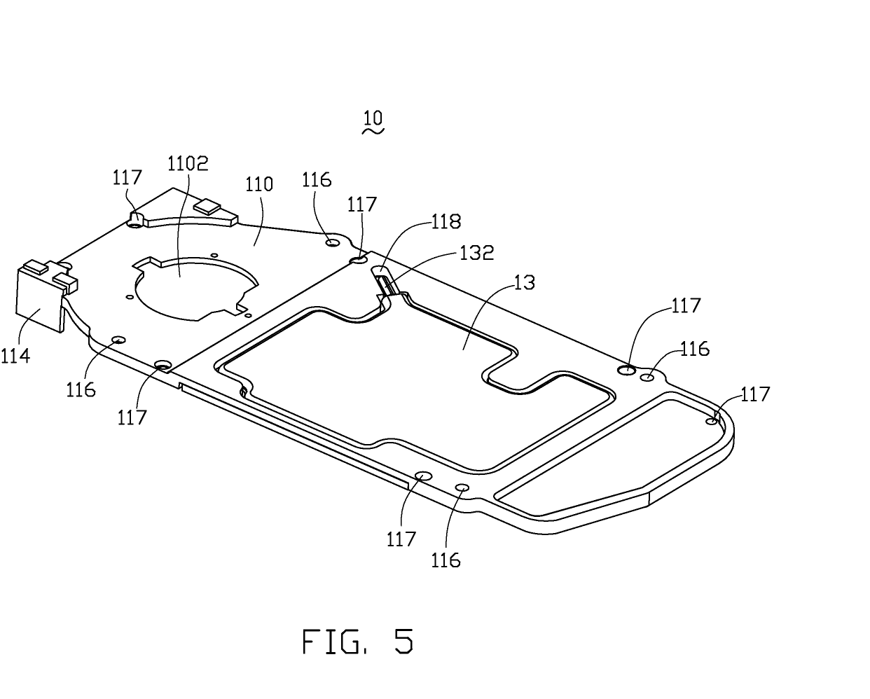

The frame 11 is integrally formed by a light metal with good heat conductivity such as aluminum for minimizing a weight of the base 10. The frame 11 defines a mounting portion 110 at one end thereof. The mounting portion 110 is substantially round in shape and is recessed from a top surface of the frame 11 for supporting the fan 30 thereon. The mounting portion 110 defines a mounting hole 1102 in a centre thereof and three mounting orifices 1104 around the mounting hole 1102 for engaging with screws 100 to secure the fan 30 thereon. The frame 11 has a plurality of flakes 114 extending upwardly from two corners thereof adjoining to the mounting portion 110. The flakes 114 whose lengths decrease sequentially from two opposite lateral sides to a middle of frame 11, are spaced from and parallel to each other and perpendicular to the top surface of the frame 11. The frame 11 defines a rectangular opening 112 adjacent to the mounting portion 110 in the other end thereof. The opening 112 is in a shape complementary with the spreader 13 for engagingly receiving the spreader 13 therein. The frame 11 is provided with a supporting flange 1120 that extends inwardly from a lower portion of an edge of the opening 112. The supporting flange 1120 is lower than a top surface of the frame 11. Portions of the supporting flange 1120 at four corner of the opening 112 extend inwardly further than remainder of the supporting flange 1120 so as to securely support the spreader 13 thereon. The frame 11 defines a plurality of countersinks 116 therein. The countersinks 116 are recessed from the top surface of the frame 11 and are located adjacent to edges thereof for receiving fixtures (not shown) to secure the base 10 to the add-on card. The frame 11 defines a plurality of fixing orifices 117 therein. The fixing orifices 117 are formed by drilling upwardly from a bottom surface of the frame 11 and are located adjacent to the edges of the frame 11, for allowing screws 200 to pass through to screw into the cover body 40. The frame 11 defines a receiving groove 118 (shown in FIG. 5) in the bottom surface thereof. The receiving groove 118 extends outwardly along a diagonal of the opening 112 to connect to a corner of the other end of the spreader 13.

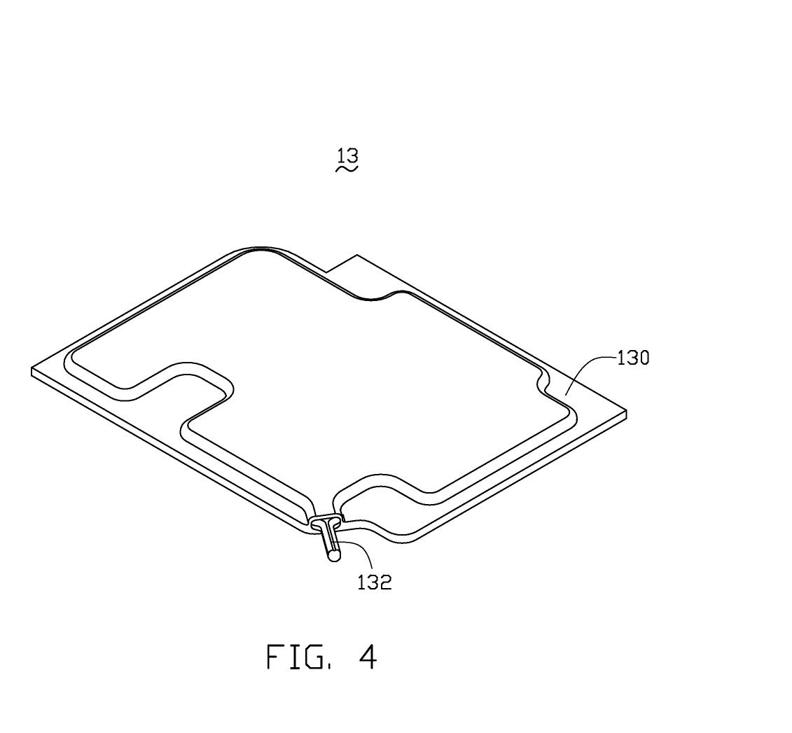

The spreader 13 is a flattened heat pipe in a plate-shape, great lighter and better heat conductive than a solid metallic plate such as copper in an equal volume. The spreader 13 defines a cavity (not shown) therein and contains working fluid in the cavity, the working fluid can take place phase change when it works. As shown in FIG. 4, the spreader 13 has a central portion thereof pressed downwardly to define a rim portion 130 around the central portion of the spreader 11 to complement the supporting flange 1120 of the frame 11. A sealed tube 132 extending outwardly and diagonally from a corner of the spreader 13 is accommodated in the receiving groove 118 in the bottom surface of the frame 11 when the spreader 13 is placed in the opening 112 of the frame 11. The top surface of the frame 11 and the spreader 13 are coplanar and form a contacting surface cooperatively, when the spreader 11 is placed in the opening 112 of the frame 11. The bottom surface of the frame 11 and a bottom surface of the central portion of the spreader 13 are coplanar.

Particularly referring to FIG. 2, the fin unit 20 comprises a plurality of fins 22 perpendicularly standing on the spreader 11. The fin unit 20 has an arched end closely surrounding the fan 30 and a radial end extending radially from the arched end. The fins 22 extend radially from the arched end to the radial end of the frame 11 remote from the fan 30. Lengths of the fins 22 are decreasing from middle toward two lateral sides of the fin unit 20. The fins 22 have flanges 220 extending perpendicularly from two opposite edges thereof. The flanges 220 are increasing in width from the arched end to the radial end of the fin unit 20, thus air passages defined between every each fin and its neighboring fins 22 become more wider further away from the arched end of the fin unit 20 for reducing air resistance in the air passage. Outlets of the air passages in the radial end of the fin unit 20 are bigger than that of inlets of the air passages in the arched end of the fin unit 20, hence the airflow produced by the fan 30 and entering the inlets can be dissipated into ambient smoothly through the outlets. The flanges 220 cooperate to form an upper surface and a lower surface which is thermally attached to the contacting surface of the base 10.

The fan 30 is a centrifugal fan. The fan 30 comprises a fan holder (not labeled) and is mounted on the mounting portion 110 of the frame 11 through the fan holder. The fan holder is engaged in the mounting hole 1102 of the mounting portion 110 and secured in place by the screws 100.

The cover body 40 comprises a top wall 42 parallel to the base 10 and a sidewall 44 extending downwardly from an edge of the top wall 42. The top wall 42 defines a circular intake 420 therein in alignment with the fan 30. A plurality of spaced fixing columns 422 extend perpendicularly from the edge of the top wall 42 for engaging with the screws 200 passing through the fixing orifices 117 in the frame 11 to secure the cover body 40 on the base 10. An exhaust 440 is formed in the sidewall 44 between the cover body 40 and the base 10. The exhaust 440 is perpendicular to the intake 420 and is positioned corresponding to the inlets of the fin unit 20.

Referring to FIGS. 1 and 2 again, in assembly of the heat dissipating device, the fin unit 20 is attached to the contacting surface of the base 10 by means like soldering and adhering. The fan 30 is mounted in the mounting portion 110 of the base 10 for producing the airflow into the air passages of the fin unit 20. The cover body 40 is secured on the base 10 by the screws 200 passing through the fixing orifices 117 of the base 10 to screw into the corresponding fixing columns 422 of the cover body 40, and encloses the fin unit 20 and the fan 30 therein.

In operation of the heat dissipation device, the heat dissipating device is mounted on the add-on card by the fixtures receiving in the countersinks 116. The spreader 13 of the base 10 is kept in intimate contact with the GPU and absorbs heat generated by the GPU. Due to the excellent heat conductivity of the spreader 13, the heat from the GPU is quickly transferred to all parts of the spreader 13, then evenly and effectively distributed to the whole fin unit 20 and finally brought into ambient by the airflow producing by the fan 30 through the air passages of the fin unit 20.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device adapted to be mounted on a heat-generating component of a graphics card, comprising:
a base adapted to be kept in intimate contact with the heat-generating component;
a fin unit comprising a plurality of fins arranged on the base and forming a plurality of air passages between each fin and its neighboring fins; and
a fan mounted on the base, close to the fin unit and producing airflow in the air passages of the fin unit;
wherein the base comprises a spreader inlayed in the base, the spreader is a flattened heat pipe, a bottom surface of the spreader is adapted to be in contact with the heat-generating component, and the fin unit is thermally attached to a top surface of the spreader.

2. The heat dissipation device as described in claim 1, wherein the base further comprises a frame which defines an opening therein, and the spreader is engagingly received in the opening.

3. The heat dissipation device as described in claim 2, wherein the frame has a supporting flange extending inwardly from a lower portion of an edge of the opening, and the spreader forms a rim portion complementary with the supporting flange, the rim portion being supported by the supporting flange.

4. The heat dissipation device as described in claim 3, wherein the spreader comprises a downwardly-pressed central portion surrounded by the rim portion, the central portion being adapted for contacting with the heat-generating component.

5. The heat dissipation device as described in claim 1, wherein the fin unit comprises an arched end surrounding the fan and a radial end extending radially from the arched end.

6. The heat dissipation device as described in claim 5, wherein the air passages each become wider from the arched end to the radial end of the fin unit.

7. The heat dissipation device as described in claim 5, wherein the fins decrease in length from a middle to two lateral sides of the base.

8. The heat dissipation device as described in claim 1, further comprising a cover body enclosing the fan and the fin unit, the cover body comprising a top wall spaced from the base and a sidewall extending downwardly from an edge of the top wall, and an intake being defined in the top wall in alignment with the fan.

9. The heat dissipation device as described in claim 8, wherein an exhaust is formed between the cover body and the base, perpendicular to the intake and corresponding to the arched end of the fin unit.

10. A heat dissipation device for cooling a heat-generating component of a graphics card, comprising:
a base for being kept in intimate contact with the heat-generating component;
a fin unit comprising a plurality of fins arranged on the base and forming a plurality of air passages between each fin and its neighboring fins; and
a centrifugal fan mounted on the base, close to the fin unit and producing airflow into the air passages of the fin unit;
wherein the fin unit comprises an arched end surrounding the fan and a radial end extending radially from the arched end.

11. The heat dissipation device as described in claim 10, wherein the air passages each become wider from the arched end to the radial end.

12. The heat dissipation device as described in claim 11, wherein the fins decrease in length from a middle to two lateral sides of the base.

13. The heat dissipation device as described in claim 10, wherein the base comprises a spreader positioned in the base, and the spreader is a flattened heat pipe whose bottom surface is for in contact with the heat-generating component.

14. The heat dissipation device as described in claim 13, wherein the fin unit is thermally attached to a top surface of the spreader.

15. The heat dissipation device as described in claim 13, wherein the base further comprises a frame with an opening defined therein, and the spreader is engagingly received in the opening.

16. The heat dissipation device as described in claim 15, wherein the frame has a supporting flange extending inwardly from a lower portion of an edge of the opening, and the spreader forms a rim portion complementary with the supporting flange, the rim portion being supported by the supporting flange.
